(19) United States
(12) Patent Application Publication
(10) Pub. No.: US 2024/0395971 A1
(43) Pub. Date: Nov. 28, 2024

(54) OPTOELECTRONIC COMPONENT, COMPONENT UNIT AND METHOD FOR PRODUCING THE SAME

(71) Applicant: ams-OSRAM International GmbH, Regensburg (DE)

(72) Inventors: Tansen Varghese, Regensburg (DE); Adrian Stefan Avramescu, Regensburg (DE); Andreas Lex, Zandt (DE)

(21) Appl. No.: 18/689,715

(22) PCT Filed: Aug. 10, 2022
(86) PCT No.: PCT/EP2022/072437

§ 371 Date: Mar. 6, 2024

(30) Foreign Application Priority Data
Sep. 8, 2021 (DE) 102021123226.0

(51) Int. Cl. H01L 33/24; H01L 33/00; H01L 33/36; H01L 33/54; H01L 33/60

(52) U.S. Cl. CPC H01L 33/24; H01L 33/0093; H01L 33/36; H01L 33/54; H01L 33/60; H01L 2933/005; H01L 2933/0058

(57) ABSTRACT

In an embodiment an optoelectronic component includes at least one semiconductor body including a first semiconductor region, a second semiconductor region and an active region therebetween, wherein the active region is configured to generate electromagnetic radiation, a cover element laterally surrounding the at least one semiconductor body and having at least one patterned side surface facing away from the at least one semiconductor body, wherein the cover element contains an index-matched material, and a reflection element, which at least partly covers the at least one patterned side surface, wherein the active region is at least partly laterally surrounded by the first semiconductor region.

### CROSS-REFERENCE TO RELATED APPLICATIONS

This patent application is a national phase filing under section 371 of PCT/EP2022/072437, filed Aug. 10, 2022, which claims the priority of German patent application 102021123226.0, filed Sep. 8, 2021, each of which is incorporated herein by reference in its entirety.

### TECHNICAL FIELD

An optoelectronic component and a component unit comprising at least two optoelectronic components are specified. In addition, a method for producing a plurality of optoelectronic components or at least one component unit is specified.

### BACKGROUND

Lateral structuring of an epitaxially grown semiconductor layer sequence in order to produce light emitting semiconductor elements may be done by etching processes. These etching processes can cause defects and non-radiative recombination at edges of the semiconductor elements, where active regions of the semiconductor elements are exposed, because of dangling bonds, which constitute non-radiative recombination centers. As the light emitting semiconductor elements become smaller, this non-radiative recombination has a bigger effect on the internal quantum efficiency of the devices.

### SUMMARY

Embodiments provide components or component units with improved radiation efficiency. Further embodiments provide an efficient method for producing a plurality of optoelectronic components or at least one component unit with improved radiation efficiency.

According to at least one embodiment of an optoelectronic component, it comprises at least one semiconductor body including a first semiconductor region, a second semiconductor region and an active region therebetween, wherein the active region is at least partly laterally surrounded by the first semiconductor region. Especially, the active region is embedded in the semiconductor body and has a lateral distance to a side surface or side surfaces of the semiconductor body. For example, the lateral distance has values in the submicron range. So, even if defects are caused by lateral structuring at edges of the semiconductor body, these defects mainly occur outside the active region. And thus, the non-radiative recombination effects are reduced.

Dependent on the geometry of the semiconductor body, it has one side surface, for example if cylindrical, or several surfaces, for example if polyhedral.

In the context of the present application, “lateral” means, for example, in a lateral direction. A lateral direction is to be understood as a direction which is essentially parallel to a main extension plane of the optoelectronic component or component unit. A vertical direction is to be understood as a direction which is essentially perpendicular to the main extension plane of the optoelectronic component. The vertical direction and the lateral direction are in particular orthogonal to each other.

For example, the side surface/s delimit/s the semiconductor body in a lateral direction or lateral directions, whereas a first main surface and a second main surface may delimit the semiconductor body in vertical directions.

According to at least one embodiment, the first semiconductor region, the active region and the second semiconductor region include epitaxially grown layers, wherein the first semiconductor region is grown after the active region, and the active region is grown before the first semiconductor region and after the second semiconductor region.

According to at least one embodiment, the active region is provided for the generation of electromagnetic radiation, wherein the optoelectronic component may be provided for the emission of electromagnetic radiation in the infrared, visible and/or ultraviolet spectral range. The active region may comprise a pn junction, a double hetero structure, a single quantum well structure (SQW structure) or a multi quantum well structure (MQW structure).

Moreover, the optoelectronic component may comprise a cover element which laterally surrounds the at least one semiconductor body. In other words, the cover element may follow the at least one semiconductor body in lateral directions.

The cover element may have at least one patterned side surface facing away from the at least one semiconductor body. For example, all side surfaces of the cover element are patterned. In this context, “patterned” means, for example, that the side surface/s result/s from a patterning process and thus may have traces of the patterning process. For example, the patterning process may be an etching process. This etching process is conducted outside the at least one semiconductor body and thus is uncritical for the internal quantum efficiency.

According to one aspect, the at least one patterned side surface is tilted. In this context, “tilted” means, for example, that the at least one side surface includes an angle with the main extension plane, wherein the angle is greater than 900 and smaller than 180°. The angle can be optimized to improve radiation emission and directionality.

According to at least one embodiment, the cover element contains an index-matched material. In this context, “index-matched material” means, for example, a material whose refractive index is matched, i.e. is similar or identical to the refractive index of the at least one semiconductor body. The cover element may contain or consist of a dielectric material. Moreover, the cover element may contain a material which is essentially transparent to the radiation emitted by the active region. Suitable materials for the cover element are oxides such as Ti₂O₃, Nb₂O₅, and Ta₂O₅.

According to at least one embodiment, the optoelectronic component comprises a reflection element, which at least partly covers the at least one patterned side surface. The reflection element may partly or completely cover all side surfaces of the cover element. The reflection element is provided to improve reflectivity at the side surface(s) of the cover element.

The reflection element may comprise or consist of at least one of the following materials: a transparent material of refractive index different from the cover element, a stack of transparent materials of different refractive index, a transparent conductive oxide, a metal or metal compound. For example, the reflection element is a part of a first electrical contact structure. In this case, the reflection element contains an electrically conductive material, for example a metal, a metal compound or a TCO (transparent conductive oxide).

According to at least one embodiment, the reflection element laterally surrounds the at least one semiconductor body. In other words, the reflection element may follow the semiconductor body in lateral directions. Moreover, the reflection element may be arranged at the first main surface of the at least one semiconductor body.

According to at least one embodiment, an optoelectronic component comprises
at least one semiconductor body including a first semiconductor region, a second semiconductor region and an active region therebetween,
a cover element, which laterally surrounds the at least one semiconductor body and has at least one patterned side surface facing away from the at least one semiconductor body,
a reflection element, which at least partly covers the at least one patterned side surface,
wherein the active region is at least partly laterally surrounded by the first semiconductor region.

According to at least one embodiment, the first semiconductor region and the second semiconductor region may each contain at least one, preferably several layers, which is/are doped. For example, the doped layer(s) of the first semiconductor region is/are of a first conductivity type, for example p-type, whereas the doped layer(s) of the second semiconductor region is/are of a second conductivity type, for example n-type. However, it may also be the other way around.

According to at least one embodiment, the semiconductor body or bodies is/are based on a III-V or a II-VI compound semiconductor material, for example on a nitride, arsenide, selenide or phosphide compound semiconductor material. “Based on a nitride, arsenide, selenide or phosphide compound semiconductor material” may mean in this context that at least one layer of the semiconductor body or bodies comprises AlnGamIn1-n-mN, AlnGamIn1-n-mAs, GaInAsP, ZnSSe or AlnGamIn1-n-mP, where 0≤n≤1, 0≤m≤1 and n+m≤1, without necessarily having a mathematically exact composition according to the above formula. Rather, it may contain one or more dopants and additional components that do not substantially alter the characteristic physical properties of the material. For the sake of simplicity, however, the above formula contains only the essential components of the crystal lattice (Al, Ga, In, N), (Al, Ga, In, As) or (Al, Ga, In, P) even if these can be partially replaced by small amounts of other substances. A quinternary semiconductor of Al, Ga, In (group III) and P and As (group V) is also possible.

According to at least one embodiment, the optoelectronic component comprises at least two semiconductor bodies, whose first semiconductor regions form one continuous region and/or whose second semiconductor regions form one continuous region. However, it is also possible for the semiconductor bodies to be separate from each other.

According to one aspect, a lateral dimension of the at least one semiconductor body may vary along the vertical direction and may range from sub-microns, for example from about 50 nm, to less than one micron. The at least one semiconductor body may have an approximately hexagonal cross-section perpendicular to the main extension plane.

According to at least one embodiment, the optoelectronic component comprises a first electrical contact structure comprising a first contact layer and further comprises a second electrical contact structure comprising a second contact layer, wherein the first and second contact layers each make electrical contact with the at least one semiconductor body. The first contact layer may comprise an electrically conductive material, for example a metal, a metal compound or a TCO. The second contact layer may comprise or consist of a semiconductor material.

Moreover, the first electrical contact structure may comprise at least one first contact element provided for electrically connecting the optoelectronic component from the outside. And the second electrical contact structure may comprise at least one second contact element provided for electrically connecting the optoelectronic component from the outside. The first and second contact elements may comprise or consist of a metal or metal compound.

For example, the first electrical contact structure may be provided for electrically connecting the first semiconductor region, wherein the first contact layer may be arranged at the first semiconductor region. The first contact layer may be arranged at the first main surface of the semiconductor body. Moreover, the first contact layer may be arranged on the side surface(s) of the cover element.

Moreover, the second contact structure may be provided for electrically connecting the second semiconductor region, wherein the second contact layer may be arranged at the second semiconductor region. However, it is also possible that the first contact structure is provided for electrically connecting the second semiconductor region, wherein the first contact layer may be arranged at the second semiconductor region. And the second contact structure may be provided for electrically connecting the first semiconductor region, wherein the second contact layer may be arranged at the first semiconductor region.

According to at least one embodiment, the first electrical contact structure comprises a vertical contact portion which covers the reflection element at the at least one patterned side surface. Moreover, the first electrical contact structure may comprise a lateral contact portion that is arranged at the first main surface of the at least one semiconductor body. The vertical contact portion may have a main extension direction in the vertical direction, whereas the lateral contact portion may extend essentially parallel to the main extension plane of the optoelectronic component. The vertical contact portion may laterally surround the at least one semiconductor body. For example, the vertical contact portion may be embodied in a frame-like manner. The vertical and lateral contact portions may comprise or consist of a metal or metal compound. The vertical and lateral contact portions may be formed from one common layer.

According to at least one embodiment, the vertical contact portion is partly arranged in an opening of the second contact layer. The vertical contact portion may be uncovered at a top side of the optoelectronic component such that it is possible to electrically contact the optoelectronic component at the top side.

According to at least one embodiment, the optoelectronic component comprises an insulation layer, wherein the insulation layer is arranged between the second contact layer and the vertical contact portion. In particular, the insulation layer is an electrically insulating layer. Suitable materials for the insulation layer are dielectric materials like SiO₂ or SixNy, for example.

The insulation layer may originate from a mask layer and may comprise at least one opening, in which one semiconductor body is partly arranged. During the production process, the mask layer may be provided for a selectively or spatially limited growth of the at least one semiconductor body on a growth substrate. So, the insulating layer may directly adjoin the semiconductor body in lateral directions. However, it is also possible for the insulation layer to be laterally spaced from the semiconductor body. For example, the cover element may be arranged between the insulation layer and the semiconductor body in lateral directions.

According to at least one embodiment, the optoelectronic component comprises a reinforcement element, wherein the at least one semiconductor body is arranged on the reinforcement element. The reinforcement element may be provided for a mechanical stabilization of the optoelectronic component. Moreover, the reinforcement element may be electrically conductive. As such, the reinforcement element can be a part of the first electrical contact structure.

According to at least one embodiment, the lateral contact portion of the first electrical contact structure may be arranged between the at least one semiconductor body and the reinforcement element.

According to at least one embodiment, the optoelectronic component comprises an additional cover element arranged between the lateral contact portion and the at least one semiconductor body. The additional cover element may have similar features as the cover element laterally surrounding the at least one semiconductor body and contains, for example, an index-matched material. Suitable materials for the additional cover element are, for example, oxides such as Ti₂O₃, Nb₂O₅ and Ta₂O₅.

According to at least one embodiment, the first contact element is arranged on a side of the reinforcement element facing away from the at least one semiconductor body. The first contact element may serve as a bonding layer.

According to at least one embodiment of a component unit comprising at least two optoelectronic components as described here, the cover elements of at least a part of the optoelectronic components are formed from one common cover layer. Moreover, the reflection elements of at least a part of the optoelectronic components may be formed from one common reflection layer. For example, the common cover layer may comprise at least one opening, in which the reflection layer is arranged. The reflection elements may contribute to optically isolate the optoelectronic components from each other.

The optoelectronic components may be individually or commonly addressable. The first electrical contact structures of at least a part of the optoelectronic components may form a common first electrical contact structure of the component unit and/or the second electrical contact structures of the same or another part of the optoelectronic components may form a common second electrical contact structure of the component unit. For example, the lateral contact portions of the first electrical contact structures may be formed as a continuous layer. Moreover, the second contact layers may be formed as a continuous layer.

According to at least one embodiment, at least one second contact element is assigned to one optoelectronic component.

Advantageously, the reflector elements and/or the vertical and/or lateral contact portions are embodied in such a way that crosstalk between the optoelectronic components can be reduced.

According to at least one embodiment, the reinforcement elements of at least a part of the optoelectronic components are formed from a common reinforcement layer.

It is possible that the component unit forms an LED array, wherein the optoelectronic components are arranged in rows and columns. The LED array is a display device, for example, wherein the semiconductor bodies may constitute pixels or subpixels.

In accordance with at least one embodiment of a method for producing a plurality of optoelectronic components or at least one component unit, the method comprises the following steps:
providing a growth substrate having a mask layer with openings arranged thereon;
forming in the openings a plurality of semiconductor bodies each including a first semiconductor region, an active region and a second semiconductor region;
forming a cover layer on the growth substrate such that the cover layer laterally surrounds at least a part of the semiconductor bodies;
patterning the cover layer to produce at least one cover element having at least one patterned side surface, wherein the patterning includes producing at least one opening in the cover layer, which is at least partly delimited by the at least one patterned side surface;
forming a reflection layer for producing reflection elements in the at least one opening of the cover layer such that it covers at least partly the at least one patterned side surface, wherein
each active region is produced such that it is at least partly laterally surrounded by the respective first semiconductor region.

The method steps may be conducted in the order as specified above.

According to at least one embodiment, the cover layer is patterned or the at least one opening is formed by etching, for example by dry etching and/or wet chemical etching.

Preferably, the individual semiconductor bodies do not undergo any singulation into smaller units. It is conceivable that the side surfaces of the semiconductor bodies are at no time exposed to a dry etching method and/or to a wet chemical etching method. The standard p-side dry etching method for forming individual semiconductor bodies from a common semiconductor layer sequence can be omitted, so that defects and non-radiative recombination centers can be reduced.

The geometry of the semiconductor bodies/optoelectronic components can be achieved by, for example:
adjusting the growth parameters used to grow the second semiconductor regions, the active regions and the first semiconductor regions,
by using crystallographic facet selective growth,
by using crystallographic facet selective growth coupled with in-situ etching,
by using crystallographic facet selective growth coupled with in-situ facet selective etching,
by using crystallographic facet selective doping.

According to at least one embodiment, the mask layer is applied to the growth substrate as a continuous layer and patterned in such a way that it comprises openings which are spaced from one another in a lateral direction. The growth substrate can be a sapphire substrate.

The plurality of the semiconductor bodies are formed in the openings. For example, the openings for semiconductor bodies of the same optoelectronic component have smaller lateral distances between them than the distances between the openings for semiconductor bodies of different optoelectronic components.

It is possible that the semiconductor bodies and/or openings have a lateral cross-section for example in the form of a circle, an ellipse or a polygon, for example in the form of a hexagon. The form of the lateral cross-section may depend partly on the crystal system of the semiconductor material of the semiconductor bodies.

According to at least one embodiment, the semiconductor bodies protrude beyond the openings along the vertical direction.

According to at least one embodiment, a reinforcement layer is arranged on a side of the semiconductor bodies facing away from the growth substrate. For example, the reinforcement layer may be electrically conductive. The reinforcement layer may comprise a Si wafer.

According to at least one embodiment, the growth substrate is detached. The reinforcement layer may serve as a substitute carrier.

According to at least one embodiment, a semiconductor layer is arranged between the growth substrate and the mask layer, wherein at least parts of the semiconductor layer form second contact layers of the semiconductor components. The semiconductor layer may be a doped layer of the second conductivity type. The semiconductor layer may be a multi-layer and comprise, for example, a buffer layer and/or current spreading layer and/or contact layer.

The method described here is suitable for the production of an optoelectronic component or component unit described here. The features described in connection with the optoelectronic component or component unit can therefore also apply to the method, and vice versa.

Further preferred embodiments and further developments of the optoelectronic component, component unit as well as of the method for producing a plurality of optoelectronic components or at least one component unit will become apparent from the exemplary embodiments explained below in conjunction with FIGS. 1 to 5.

### BRIEF DESCRIPTION OF THE DRAWINGS

FIGS. 1A to 1I show schematic illustrations of some method steps of an exemplary embodiment of a method for the production of a component unit or an optoelectronic component, and FIG. 1I shows an exemplary embodiment of a component unit;

FIG. 2A shows a schematic cross-sectional view of an exemplary embodiment of an optoelectronic component;

FIGS. 2B and 2C show lateral cross-sectional views of exemplary embodiments of semiconductor bodies included in the optoelectronic component; and

FIGS. 3 to 5 show schematic cross-sectional views of further exemplary embodiments of methods for the production of component units, of component units and optoelectronic components.

### DETAILED DESCRIPTION OF ILLUSTRATIVE EMBODIMENTS

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

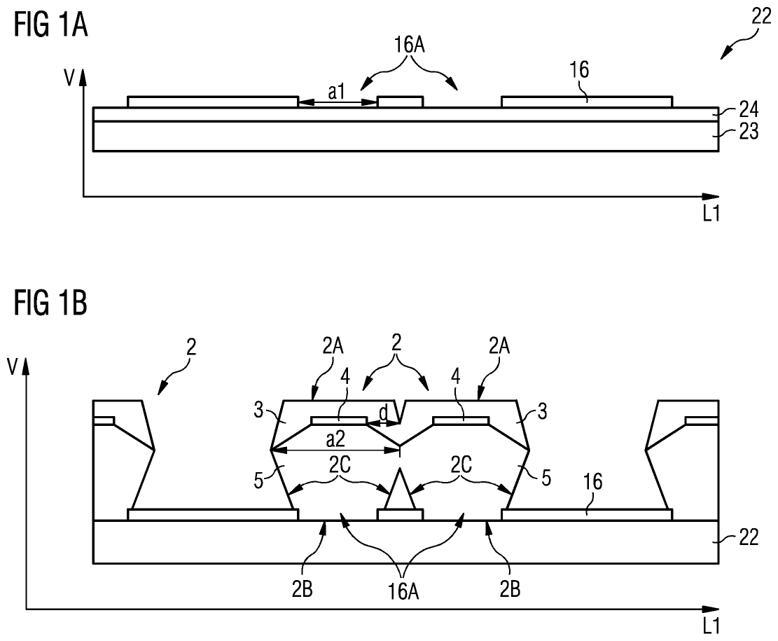

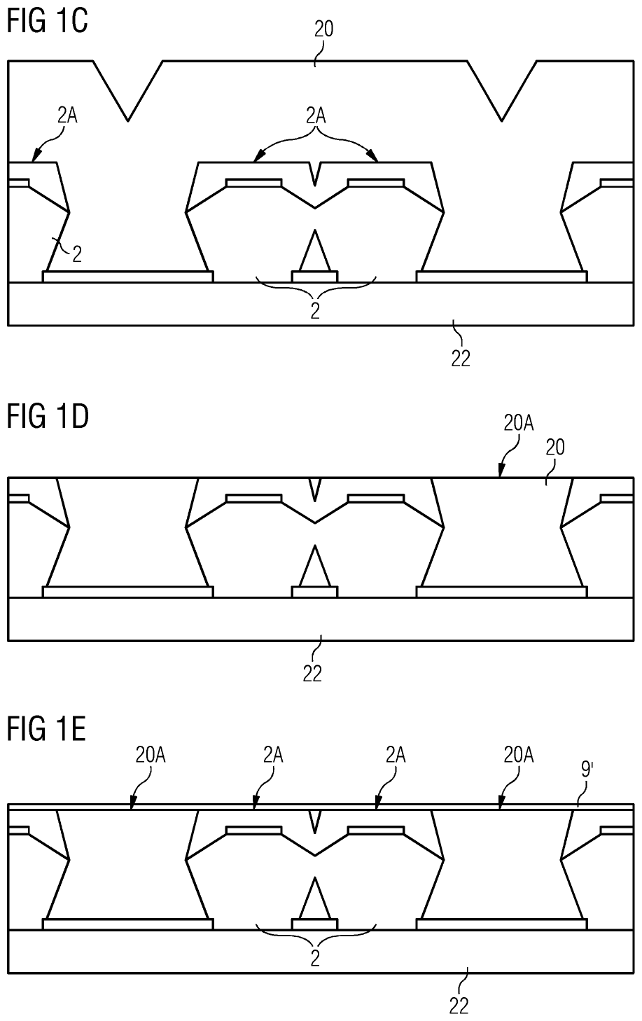

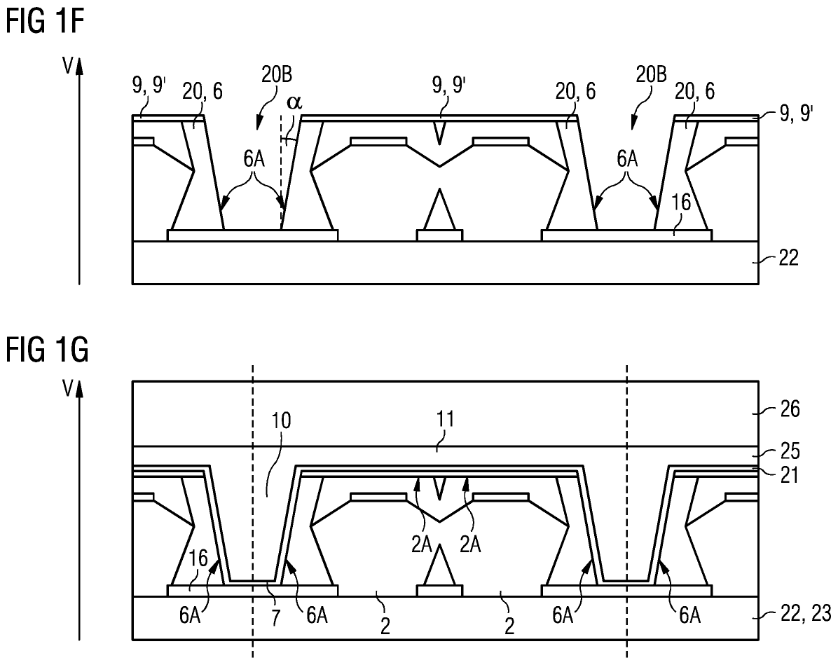

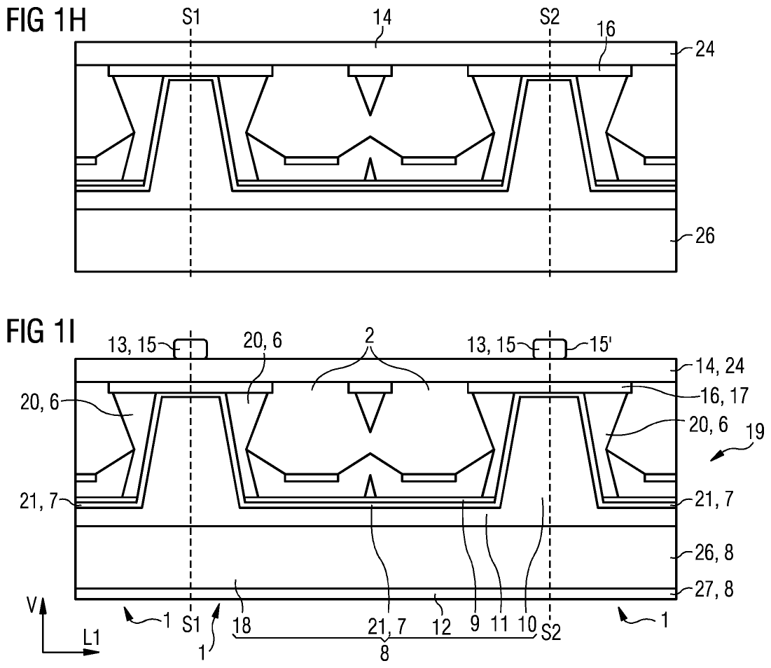

According to an exemplary embodiment of a method for producing a plurality of optoelectronic components or at least one component unit, the method comprises providing a growth structure 22 comprising a growth substrate 23 having a mask layer 16 with openings 16A arranged thereon (see FIG. 1A). For example, the growth substrate 23 is a sapphire substrate. Moreover, the mask layer 16 may comprise dielectric materials like SiO₂ or SixNy, for example. The mask layer 16 is applied to the growth substrate 23 as a continuous layer and patterned in such a way that it comprises the openings 16A, which are spaced from one another in a lateral direction L1.

The lateral direction L1 is essentially parallel to a main extension plane of the growth substrate 23. A vertical direction V is to be understood as the direction which is essentially perpendicular to the main extension plane of the growth substrate 23. The vertical direction V and the lateral direction L1 are in particular orthogonal to each other.

The openings 16A each have a first lateral dimension a1 along the first lateral direction L1 ranging from about 50 nm to about one micron, for example.

A semiconductor layer 24 is arranged between the growth substrate 23 and the mask layer 16. The semiconductor layer 24 may be a doped layer of a second conductivity type, wherein the second conductivity type may be n-type. The semiconductor layer 24 may be a multi-layer comprising a buffer layer as well as a spreading and contact layer. The semiconductor layer 24 may be based on the same semiconductor material as the semiconductor bodies which are grown on the growth structure 22. The semiconductor layer 24 may be formed from GaN.

The method further comprises forming a plurality of semiconductor bodies 2 each including a first semiconductor region 3, an active region 4 and a second semiconductor region 5 in the openings 16A of the mask layer 16 (see FIG. 1B). For example, the first semiconductor regions 3, the active regions 4 and the second semiconductor regions 5 are epitaxially grown on the growth structure 22.

Especially, the mask layer 16 is provided for a selectively or spatially limited growth of the semiconductor bodies 2 on the growth substrate 23. The second semiconductor regions 5 may be first grown on the growth structure 22 followed by the active regions 4, which are followed by the first semiconductor regions 3. The semiconductor bodies 2 protrude beyond the openings 16A in the vertical direction V.

Each active region 4 is produced such that it is laterally surrounded by the respective first semiconductor region 3. Especially, each active region 4 is embedded in the respective semiconductor body 2 and has a lateral distance d to side surfaces 2C of the respective semiconductor body 2. The lateral distance d has values in the submicron range.

The side surfaces 2C delimit the semiconductor body 2 in lateral directions, whereas a first main surface 2A and a second main surface 2B delimit the semiconductor body 2 in vertical directions. For example, each side surface 2C connects the first main surface 2A to the second main surface 2B. As becomes evident from FIG. 1B, the side surfaces 2C may be angled. However, it is also possible for the side surfaces 2C to be planar. A lateral dimension a2 of the semiconductor bodies 2 varies along the vertical direction V and may range from sub-microns, for example from about 50 nm, to about one micron. The semiconductor bodies 2 can have an approximately hexagonal cross-section perpendicular to the main extension plane.

Given the lateral distances d of the active regions 4 to the side surfaces 2C, the effect of defects and non-radiative recombination centers on the internal quantum efficiency is reduced even if defects are caused by lateral structuring at edges of the semiconductor bodies 2, because the defects mainly occur outside the active regions 4.

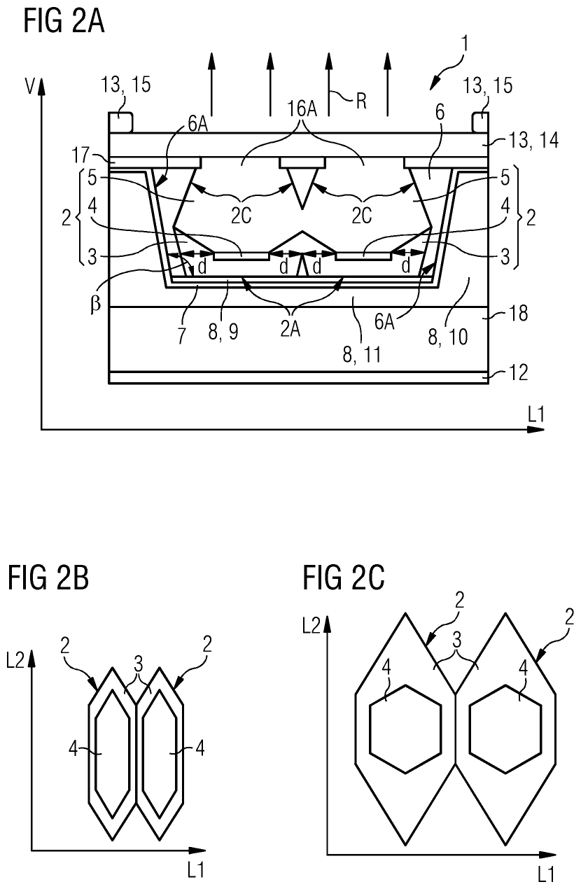

The semiconductor bodies 2 and/or openings 16A may have a lateral cross-section for example in the shape of a hexagon (see FIGS. 2B and 2C). The shape of the semiconductor bodies 2 may depend inter alia on the crystal system of the semiconductor material of the semiconductor bodies 2, which may have a wurtzite structure. As mentioned above, the semiconductor material may be based on a III-V or a II-VI compound semiconductor, for example on a nitride, arsenide, selenide or phosphide compound semiconductor.

Moreover, as mentioned above, the geometry of the semiconductor bodies 2/optoelectronic components 1 can be achieved by, for example:
adjusting growth parameters used to grow the second semiconductor regions 5, the active regions 4 and the first semiconductor regions 3,
by using crystallographic facet selective growth,
by using crystallographic facet selective growth coupled with in-situ etching,
by using crystallographic facet selective growth coupled with in-situ facet selective etching,
by using crystallographic facet selective doping.

The method further comprises forming a cover layer 20 for producing cover elements on the growth structure 22 or growth substrate 23 such that the cover layer 20 laterally surrounds at least a part of the semiconductor bodies 2 (see FIG. 1C). Moreover, the cover layer 20 is deposited on the first main surfaces 2A of the semiconductor bodies 2.

The cover layer 20 is formed, for example, from an index-matched material as mentioned above, wherein suitable materials are, for example, oxides such as Ti₂O₃, Nb₂O₅ or Ta₂O₅.

The method further comprises removing the part of the cover layer 20 deposited on the first main surfaces 2A of the semiconductor bodies 2 until the first main surfaces 2A are reached (see FIG. 1D). The removal process may lead to a planar surface 20A of the cover layer 20. For example, the removal process may be a chemical mechanical polishing process.

The method further comprises applying a first contact layer 9′ on the surface 20A of the cover layer 20 and on the main surfaces 2A of the semiconductor bodies 2 (see FIG. 1E) in order to form first contact layers 9 in the devices 1, 19 to be produced (see FIGS. 1I and 2A). The first contact layer 9′ is formed from an electrically conductive material, for example from a metal, a metal compound or a TCO.

The method further comprises patterning the cover layer 20 to produce cover elements 6 each having patterned side surfaces 6A (see FIG. 1F). The pattering process includes producing openings 20B in the cover layer 20, which are each delimited by patterned side surfaces 6A of the cover elements 6. In the vertical direction V, the openings 20B fully penetrate the cover layer 20. In this embodiment, the mask layer 16 is arranged at the bottom of each opening 20B.

In this embodiment, the patterned side surfaces are tilted and deviate from the vertical direction V by an angle α that can be optimized to improve radiation emission and directionality.

Moreover, the patterning process includes patterning the first contact layer 9′ to produce a plurality of first contact layers 9, wherein one first contact layer 9 is assigned to one optoelectronic component 1 (see FIG. 1I).

The patterning process is an etching process, for example.

The method further comprises forming a reflection layer 21 for producing reflection elements 7 in the openings 20B of the cover layer 20 such that it covers the patterned side surfaces 6A (see FIG. 1G). Moreover, the reflection layer 21 covers the first main surfaces 2A of the semiconductor bodies 2. The reflection layer 21 may be formed as mentioned above from at least one of the following materials: a transparent material of refractive index different from the cover element 6, a stack of transparent materials of different refractive index, a transparent conductive oxide, a metal or metal compound.

The method further comprises applying a contact portion layer 25 on the reflection layer 21 provided to form vertical contact portions 10 and lateral contact portions 11 in the devices to be produced. The contact portion layer 25 is formed from an electrically conductive material or materials like metals or metal compounds.

The method further comprises applying a reinforcement layer 26 to produce reinforcement elements 18 on a side of the semiconductor bodies 2 facing away from the growth substrate 23 or growth structure 22. The reinforcement layer 26 covers the contact portion layer 25 on a surface facing away from the growth substrate 23. For example, the reinforcement layer 26 may be electrically conductive and may comprise a Si wafer.

The method further comprises detaching the growth substrate 23 or detaching the growth structure 22 right down to the semiconductor layer 24 (see FIG. 1H). Advantageously, the reinforcement layer 26 serves as a substitute carrier. Moreover, parts of the semiconductor layer 24 form second contact layers 14 in the final products.

The method further comprises applying second contact portions 15′ on the semiconductor layer 24 (see FIG. 1I). The second contact portions 15′ may be formed from a metal or metal compound. The second contact portions 15′ may each have a strip-like shape. The second contact portions 15′ may be arranged in a grid-like manner. The second contact portions 15′ may be divided into second contact elements 15.

The method further comprises applying a first contact element layer 27 to produce first contact elements 12 on a surface of the reinforcement layer 26 facing away from the semiconductor bodies 2.

FIG. 1I shows an exemplary embodiment of a component unit 19, which may result from the wafer composite produced by the method described in connection with FIGS. 1A to 1I.

The component unit 19 comprises several optoelectronic components 1 which are unseparated in the component unit 19 and may be singulated along singulation planes S1, S2, wherein the singulation planes S1, S2 are arranged essentially parallel to the vertical direction V and a second lateral direction L2 (see FIGS. 2B and 2C), which is essentially perpendicular to the vertical direction V and the first lateral direction L1. The component unit 19 can be left un-singulated, for example as a μLED array.

In the component unit 19, the cover elements 6 of the optoelectronic components 1 are formed from a common cover layer 20 (see FIGS. 1E and 1F). And their reflection elements 7 are formed from one common reflection layer 21 (see FIG. 1G). The common cover layer 20 comprises openings 20B, in which the reflection layer 21 is arranged.

In the component unit 19, first electrical contact structures 8 of the optoelectronic components 1 each comprising the first contact layer 9, the vertical and lateral contact portions 10, 11, the reflection element 7, the reinforcement element 18 and the first contact element 12 form a common first electrical contact structure of the component unit 19, and the second electrical contact structures 13 of the optoelectronic components 1 each comprising the second contact layer 14 and second contact elements 15 form a common second electrical contact structure of the component unit 19. The structured mask layer 16 is arranged between the vertical contact portions 10 and the second contact layers 14 and forms a common insulation layer therebetween. In this embodiment, the optoelectronic components 1 or their semiconductor bodies 2 are not individually addressable. However, the first and second electrical contact structures 8, 13 can be modified such that the optoelectronic components 1 or their semiconductor bodies 2 are individually addressable.

Advantageously, the reflector elements 7 and the vertical and lateral contact portions 10, 11, are embodied in such a way that crosstalk between the optoelectronic components 1 can be reduced.

The optoelectronic components 1 are arranged, for example, in rows and columns. The component unit 19 may constitute an LED array, wherein the semiconductor bodies 2 may constitute pixels or subpixels.

In connection with FIG. 2A, an exemplary embodiment of an optoelectronic component 1 is described, which can be produced by the method described in connection with FIGS. 1A to 1I or by singulation of the component unit 19 as described in connection with FIG. 1I.

The optoelectronic component 1 comprises several semiconductor bodies 2 each including a first semiconductor region 3, a second semiconductor region 5 and an active region 4 therebetween. The first semiconductor region 3 and the second semiconductor region 5 may each contain at least one, preferably several layers, which is/are doped. For example, the doped layer(s) of the first semiconductor region 3 is/are of a first conductivity type, for example p-type, whereas the doped layer(s) of the second semiconductor region 5 is/are of a second conductivity type, for example n-type. However, it may also be the other way around.

The active regions 4 are provided for the generation of electromagnetic radiation, wherein the optoelectronic component 1 may emit radiation R in the infrared, visible and/or ultraviolet spectral range, for example. The active region 4 may comprise a pn junction, a double hetero structure, a single quantum well structure (SQW structure) or a multi quantum well structure (MQW structure).

As mentioned above, the semiconductor bodies 2 are based on a III-V or a II-VI compound semiconductor material, for example on a nitride, arsenide, selenide or phosphide compound semiconductor material.

The first semiconductor regions 3 of the semiconductor bodies 2 form one continuous region and the second semiconductor regions 5 form one continuous region. However, the active regions 4 are laterally spaced from each other. Each active region 4 is laterally surrounded by the respective first semiconductor region 3 and has a lateral distance d to side surfaces 2C of the respective semiconductor body 2. For example, the lateral distances d have values in the submicron range. So, even if defects are caused by lateral structuring at edges of the semiconductor bodies 2, these defects mainly occur outside the active regions 4. And thus, the non-radiative recombination effects are reduced.

The optoelectronic component 1 comprises a cover element 6 which laterally surrounds the semiconductor bodies 2. The cover element 6 has patterned side surfaces 6A facing away from the semiconductor bodies 2. The patterned side surfaces 6A are tilted. In this context, “tilted” means that the side surfaces 6A include an angle β with a main extension plane, wherein the angle β can be greater than 900 and smaller than 180°. The angle β can be optimized to improve radiation emission and directionality.

Furthermore, the optoelectronic component 1 comprises a reflection element 7, which covers the patterned side surfaces 6A and is arranged at first main surfaces 2A of the semiconductor bodies 2. The reflection element 7 may comprise or consist of at least one of the following materials: a transparent material of refractive index different from the cover element 6, a stack of transparent materials of different refractive index, a transparent conductive oxide, a metal or metal compound.

The cover element 6 contains an index-matched material and is essentially transparent for the radiation emitted by the active regions 4. As a consequence, laterally emitted radiation may reach the patterned side surfaces 6A without being refracted at the side surfaces 2C of the semiconductor bodies 2. The cover element 6 contains a dielectric material, for example an oxide such as Ti₂O₃, Nb₂O₅, and Ta₂O₅. The laterally emitted radiation may be reflected at the patterned side surfaces 6A by the reflection element 7.

So, the optoelectronic component 1 as well as the component unit 19 described above have an optimized radiation efficiency due inter alia to the optimized internal quantum efficiency, reflectivity and directionality.

The optoelectronic component 1 comprises a reinforcement element 18, on which the semiconductor bodies 2 are arranged. The reinforcement element 18 mechanically stabilizes the optoelectronic component 1. Moreover, the reinforcement element 18 may be electrically conductive.

The optoelectronic component 1 comprises a first electrical contact structure 8, wherein the first electrical contact structure 8 can comprise:
a first contact layer 9 arranged at the first semiconductor region 3,
the reflection element 7,
a vertical contact portion 10 and a lateral contact portion 11, which cover the reflection element 7,
the reinforcement element 18, wherein the lateral contact portion 11 is arranged between the semiconductor bodies 2 and the reinforcement element 18, and
a first contact element 12 arranged on a side of the reinforcement element 18 facing away from the semiconductor bodies.

The first contact layer 9 may comprise an electrically conductive material, for example a metal, a metal compound or a TCO. The first contact element 12 may comprise or consist of a metal or metal compound and may serve as a bonding layer.

The vertical contact portion 10 has a main extension direction in the vertical direction V, whereas the lateral contact portion 11 extends essentially parallel to a main extension plane L1-L2 of the optoelectronic component 1. The vertical contact portion 10 laterally surrounds the semiconductor bodies 2 and is embodied in a frame-like manner. The vertical and lateral contact portions 10, 11 may comprise or consist of a metal or metal compound.

Moreover, the optoelectronic component 1 comprises a second electrical contact structure 13, wherein the second electrical contact structure 13 comprises a second contact layer 14 and a second contact element 15, which can be shaped in a frame-like manner, or second contact elements 15, which can be shaped in a strip-like manner. The second contact layer 14 may comprise or consist of a semiconductor material. The second contact element(s) 15 may comprise or consist of a metal or metal compound.

The first contact structure 8 is provided for electrically connecting the first semiconductor region 3. And the second contact structure 13 is provided for electrically connecting the second semiconductor region 5. Moreover, the first contact element 12 and the second contact element(s) 15 are provided for electrically connecting the optoelectronic component 1 from the outside.

The optoelectronic component 1 comprises an insulation layer 17, wherein the insulation layer 17 is arranged between the vertical contact portion 10 and the second contact layer 14. The insulation layer 17 is an electrically insulating layer, which electrically insulates the second contact structure 13 from the first contact structure 8. Suitable materials for the insulation layer 17 are dielectric materials like SiO₂ or SixNy, for example.

The insulation layer 17 originates from a mask layer 16 (see FIG. 1A) and comprises openings 16A, wherein one semiconductor body 2 is partly arranged in one opening 16A. The insulation layer 17 directly adjoins the semiconductor bodies 2 in lateral directions L1, L2.

As becomes evident from FIGS. 2B and 2C, the semiconductor bodies 2 may have a lateral cross-section parallel to plane L1-L2 in the shape of a hexagon. The shape of the lateral cross-section may depend on the crystal system of the semiconductor material of the semiconductor bodies 2. The semiconductor material of the semiconductor bodies 2 shown in FIGS. 2B and 2C may be InAlGaN. Even though the lateral cross-sections of both embodiments are hexagonal, the shapes of the hexagons are slightly different. Different material systems and/or embodiments can have different shapes.

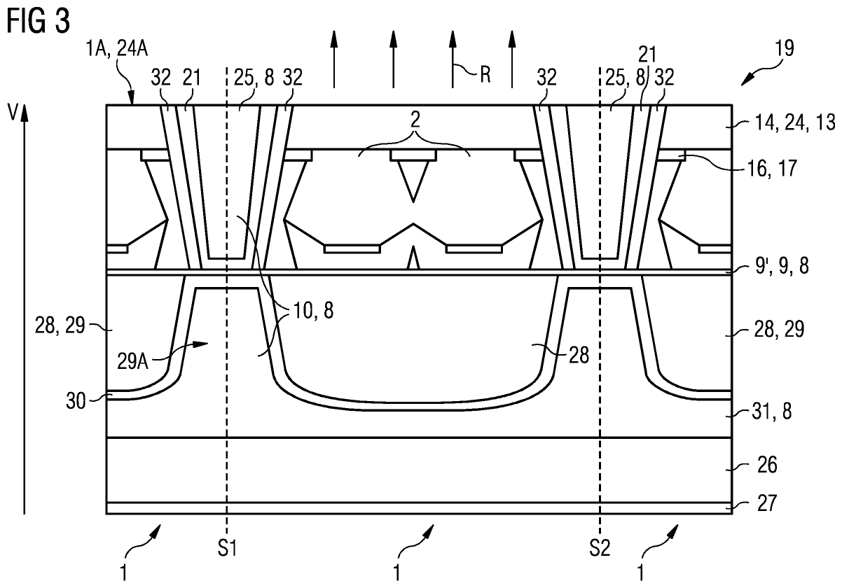

FIG. 3 illustrates a further exemplary embodiment of a method or component unit 19 comprising several optoelectronic components 1. The optoelectronic components 1 each comprise an additional cover element 28 on a side of the first contact layer 9 facing away from the semiconductor bodies 2.

The additional cover elements 28 may be formed from an additional cover layer 29, which may be applied to the wafer composite after the production of the first contact layer 9′ (see FIG. 1E). The additional cover layer 29 may be patterned including forming openings 29A in the additional cover layer 29.

Moreover, an additional reflection layer 30 is arranged on the additional cover layer 29 extending into the openings 29A.

An additional contact portion layer 31 is arranged on the additional reflection layer 30 extending into the openings 29A. The reinforcement layer 26 is adjacent to the additional contact portion layer 31, and the first contact element layer 27 is formed on the reinforcement layer 26.

In the following, the cover layer 20 embedding the semiconductor bodies 2, the mask layer 16 and the semiconductor layer 24 may be patterned including forming openings extending from a main surface 24A of the semiconductor layer 24 until the first contact layer 9′. An additional insulation layer 32, the reflection layer 21 and the contact portion layer 25 are formed in this order on the wafer composite.

In the optoelectronic components 1 according to this exemplary embodiment, the reflection elements 7 are each multilayered as being formed from two reflection layers 21, 30 arranged on top of each other, wherein the layers 21, 30 are separated by the first contact layer 9′ in the vertical direction V.

Moreover, the lateral contact portions 11 are each arranged between the additional cover element 28 and the reinforcement element 18.

The optoelectronic components 1 each comprise a multilayered vertical contact portion 10 formed from two layers 25, 31 arranged on top of each other and separated by the two reflection layers 21, 30 and the first contact layer 9′ in the vertical direction V. Moreover, the vertical contact portion 10 is uncovered at a top side 1A of the component 1, which allows for a top side connection of the component 1 given that both electrical contact structures 8, 13 reach the top side 1A.

Apart from that, the component unit 19 and the optoelectronic components 1 included therein may comprise the features and advantages explained in connection with the aforementioned exemplary embodiments, in particular an optimized internal quantum efficiency, reflectivity and directionality.

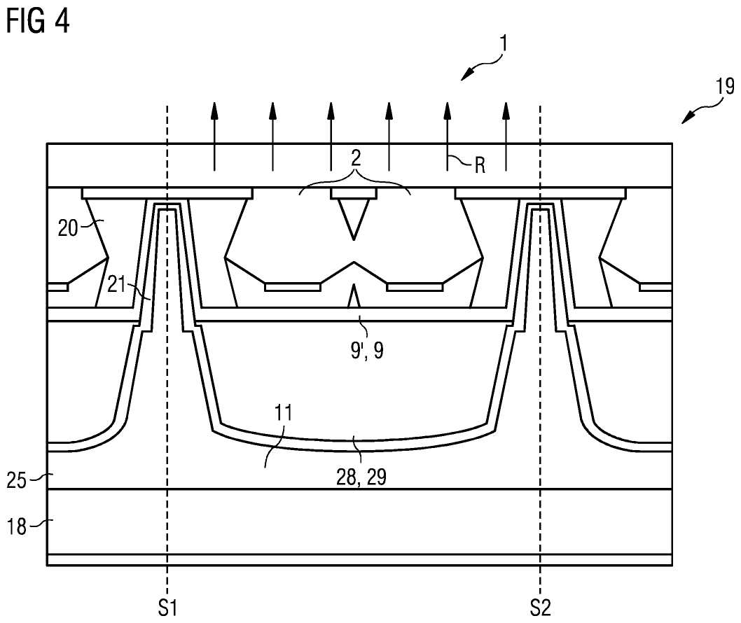

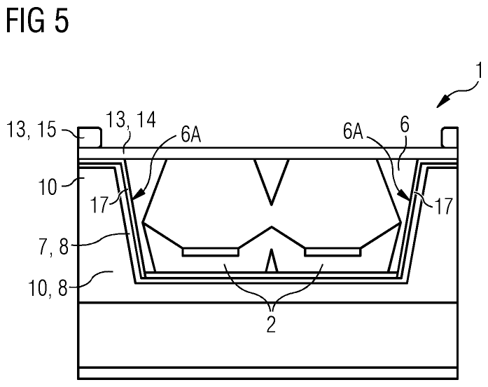

FIG. 4 illustrates a further exemplary embodiment of a method or component unit 19 comprising several optoelectronic components 1.

In this exemplary embodiment, the optoelectronic components 1 each comprise an additional cover element 28 on a side of the first contact layer 9 facing away from the semiconductor bodies 2, wherein the openings in the additional cover layer 29 are produced after patterning the cover layer 20 and producing the first contact layer 9′ on the patterned cover layer 20, wherein the first contact layer 9′ extends into the openings of the cover layer 20.

The reflection layer 21 and the contact portion layer 25 are applied on the additional cover layer 29 extending into the openings of the cover layers 20, 29.

In this exemplary embodiment, the lateral contact portions 11 are each arranged between the additional cover element 28 and the reinforcement element 18.

Apart from that, the component unit 19 and the optoelectronic components 1 included therein may comprise the features and advantages explained in connection with the aforementioned exemplary embodiments, in particular an optimized internal quantum efficiency, reflectivity and directionality.

FIG. 5 illustrates a further exemplary embodiment of an optoelectronic component 1. In this exemplary embodiment, the mask layer used for the selective growth of the semiconductor bodies 2 has been removed. In order to electrically insulate the first electrical contact structure 8 from the second electrical contact structure 13, an insulating layer is arranged in the openings of the cover layer before the reflection layer is arranged during the production process. So, the optoelectronic component 1 comprises an insulating layer 17 arranged on the patterned side surfaces 6A of the cover element 6. Moreover, the insulating layer 17 is arranged between the vertical contact portion 10 and the second contact layer 14. The insulation layer 17 is laterally spaced from the semiconductor bodies 2, wherein the cover element 6 is arranged between the insulation layer 17 and the semiconductor bodies 2 in lateral directions.

Apart from that, the optoelectronic component 1 may comprise the features and advantages explained in connection with the aforementioned exemplary embodiments, in particular an optimized internal quantum efficiency, reflectivity and directionality.

The invention is not limited to these embodiments by the description based on the embodiments. Rather, the invention includes any new feature and any combination of features, which includes in particular any combination of features in the patent claims, even if this feature or this combination itself is not explicitly explained in the patent claims or embodiments.

1.-17. (canceled)

18. An optoelectronic component comprising:
at least one semiconductor body including a first semiconductor region, a second semiconductor region and an active region therebetween, wherein the active region is configured to generate electromagnetic radiation;
a cover element laterally surrounding the at least one semiconductor body and having at least one patterned side surface facing away from the at least one semiconductor body, wherein the cover element contains an index-matched material; and
a reflection element, which at least partly covers the at least one patterned side surface, wherein the active region is at least partly laterally surrounded by the first semiconductor region.

19. The optoelectronic component according to claim 18, wherein the reflection element laterally surrounds the at least one semiconductor body.

20. The optoelectronic component according to claim 18, wherein the optoelectronic component comprises at least two semiconductor bodies, whose first semiconductor regions form one continuous region and/or whose second semiconductor regions form one continuous region.

21. The optoelectronic component according to claim 18, further comprising:
a first electrical contact structure comprising a first contact layer; and
a second electrical contact structure comprising a second contact layer,
wherein each of the first and second contact layers is in electrical contact with the at least one semiconductor body.

22. The optoelectronic component according to claim 21, wherein the first electrical contact structure comprises a vertical contact portion covering the reflection element at the at least one patterned side surface.

23. The optoelectronic component according to claim 22, further comprising an insulation layer arranged between the vertical contact portion and the second contact layer.

24. The optoelectronic component according to claim 23, wherein the insulation layer originates from a mask layer and comprises at least one opening, in which one semiconductor body is partly arranged.

25. The optoelectronic component according to claim 21, further comprising a reinforcement element, on which the at least one semiconductor body is arranged, wherein a lateral contact portion of the first electrical contact structure is arranged between the at least one semiconductor body and the reinforcement element.

26. A component unit comprising at least two optoelectronic components according to claim 21, wherein the cover elements of at least a part of the optoelectronic components are formed from one common cover layer.

27. The component unit according to claim 26, wherein the reflection elements of at least a part of the optoelectronic components are formed from one common reflection layer.

28. The component unit according to claim 27, wherein the common cover layer comprises at least one opening, in which the reflection layer is arranged.

29. The component unit according to claim 26,
wherein the first electrical contact structures of at least a part of the optoelectronic components form a common first electrical contact structure of the component unit, and/or
wherein the second electrical contact structures of the same or another part of the optoelectronic components form a common second electrical contact structure of the component unit.

30. The optoelectronic component according to claim 18, wherein the at least one patterned side surface is tilted and includes an angle with a main extension plane, wherein the angle is greater than 900 and smaller than 180°, and wherein the angle is optimized to improve radiation emission and directionality.

31. A method for producing a plurality of optoelectronic components, each being the optoelectronic component according to claim 18, the method comprising:
providing a growth substrate having a mask layer with openings arranged thereon;
forming, in the openings, a plurality of semiconductor bodies;
forming a cover layer on the growth substrate such that the cover layer laterally surrounds at least a part of the semiconductor bodies;
patterning the cover layer to produce at least one cover element containing the index-matched material and having the at least one patterned side surface, wherein patterning includes producing at least one opening in the cover layer, which is at least partly delimited by the at least one patterned side surface; and
forming a reflection layer for producing reflection elements in the at least one opening of the cover layer such that it covers at least partly the at least one patterned side surface,
wherein each active region is produced such that it is at least partly laterally surrounded by the respective first semiconductor region.

32. The method according to claim 31, further comprising arranging a reinforcement layer on a side of the semiconductor bodies facing away from the growth substrate.

33. The method according to claim 31, further comprising detaching the growth substrate.

34. The method according to claim 31, wherein a semiconductor layer is arranged between the growth substrate and the mask layer, and wherein at least parts of the semiconductor layer form second contact layers of the optoelectronic components.
